(19) United States
(12) Patent Application Publication
(10) Pub. No.: US 2018/0267378 A1
(43) Pub. Date: Sep. 20, 2018

(54) LIQUID CRYSTAL DISPLAY PANEL AND LIQUID CRYSTAL DEVICE

(71) Applicant: Wuhan China Star Optoelectronics Technology Co., Ltd., Wuhan, Hubei (CN)

(72) Inventors: Man LI, Wuhan, Hubei (CN); Qingcheng ZUO, Wuhan, Hubei (CN); Xiaoling YUAN, Wuhan, Hubei (CN)

(21) Appl. No.: 15/549,060

(22) PCT Filed: Apr. 18, 2017
(86) PCT No.: PCT/CN2017/080947

§ 371 Date: Aug. 4, 2017

(30) Foreign Application Priority Data
Mar. 17, 2017 (CN) 201710159802.0

(51) Int. Cl. G02F 1/1362; G02F 1/1333; G02F 1/133; G09G 3/36; H01L 27/12

(52) U.S. Cl. CPC G02F 1/136286; G02F 1/133308; H01L 27/124; G02F 1/136204; G09G 3/36; G02F 1/13306

(57) ABSTRACT

A liquid crystal display panel having a display zone and a non-display zone surrounding the display zone is provided. The non-display zone defines multiples areas for arrange a driving chip, a plurality of fan-out wires, a plurality of multiplex lines, a shielding circuit, and detection circuit. The detection circuit includes a detection line conducting at a forward-bias state and cutting-off at a reverse-bias state.

### BACKGROUND

### 1. Field of the Disclosure

The present disclosure relates to the field of a liquid crystal display, and more particularly, to a liquid crystal display panel and a liquid crystal device with the liquid crystal display panel.

### 2. Description of the Related Art

Liquid crystal displays (LCDs), with advantages of thin body, energy-saving, radiation-free, etc., are widely applied to a variety of technical products such as mobile phones, personal digital assistants (PDAs), digital cameras, computer screens, notebook computer screens.

FIG. 1 is a schematic diagram of a common LCD of the related art. In addition to a display zone, an LCD screen includes a corresponding circuit structure surrounding the LCD screen such as a gate driver on array (GOA) circuit at the left and right side of the display zone 101. An array substrate test zone is arranged on the display zone 101. A driver chip bonding zone 102, a fan-out wire 103, a panel detection circuit zone 104, a multiplex line zone 105, a shielding zone 107, etc. are arranged below the display zone 101. In this way, it is very hard to narrow down the non-display zone 106 (i.e., the bezel) surrounding the display zone 101 to a large scale because it is impossible to omit these necessary function circuits. The display zone 101 is the broadest especially the lower side of the display zone 101 because the driver chip bonding zone 102 and a flexible printed circuit (FPC) are bonded below the display zone 101.

As FIG. 2 shows, a driver chip 201, a fan-out wire 202, a panel detection circuit 203, and a multiplex line 204 are shown. A detection control signal CTEN, an odd node detection signal DO, and an even node detection signal DE are fed to the panel detection circuit 203. The detection control signal CTEN is used to enable the panel detection circuit 203. The odd node detection signal DO and the even node detection signal DE both are data signals output to the odd and even data lines. The detection control signal CTEN controls the input of the odd node detection signal DO and the even node detection signal DE through a thin-film transistor (TFT). With the TFT, the width of the panel detection circuit 203 should not be too small.

In sum, the liquid crystal display panel of the related art is hard to be equipped with a narrow bezel because a panel detection circuit occupies the bezel too much.

### SUMMARY

A liquid crystal display panel proposed by the present disclosure is equipped with a detection line with a simple structure which is replaced with a panel detection circuit to solve the problem occurring in the related art. In the related art, the panel detection circuit occupies a larger part of the bezel, which is the cause of realization of a liquid crystal display panel with a narrow bezel.

According to one aspect of the present disclosure, a liquid crystal display panel having a display zone and a non-display zone surrounding the display zone is provided. A driver unit is arranged in the non-display zone. The driver unit includes a plurality of fan-out wires, a plurality of multiplex lines, a shielding circuit, and a plurality of fuses. A driver signal is input to an input terminal of the fan-out wire. An output terminal of the fan-out wire extends to the display zone and is connected to a data line connected to each pixel. The plurality of fan-out wires are configured to drive transmittance of voltage. Each of the plurality of multiplex lines is connected to some of the plurality of fan-out wires, and is configured to conduction and disconnection of the connected fan-out wire. The shielding circuit adjoining the display zone is configured to protect the liquid crystal display panel from static. An input terminal of the fuse is connected to a detection signal source. An output terminal of the fuse is connected to the fan-out wire correspondingly. An output terminal of the fan-out wire is connected to the multiplex line. The multiplex line is connected to an input terminal of the data line. The data line is connected to a thin-film transistor (TFT) in the shielding circuit and then each of the pixels in the display zone. The plurality of fuses are configured to detect a circuit in the display zone.

According to an embodiment of the present disclosure, the detection signal source comprises a detection signal line. The fuse and the detection signal line are connected in parallel.

According to an embodiment of the present disclosure, the fuse is arranged in a driver chip bonding zone of the non-display zone.

According to an embodiment of the present disclosure, a driver chip is bonded to the driver chip bonding zone after the detection of the panel is completed. A pin of the driver chip is connected to the fan-out wire correspondingly.

According to another aspect of the present disclosure, a liquid crystal display panel having a display zone and a non-display zone surrounding the display zone is provided. A driver unit is arranged in the non-display zone. The driver unit includes a plurality of fan-out wires, a plurality of multiplex lines, a shielding circuit, and a plurality of fuses. Each of the plurality of multiplex lines is connected to some of the plurality of fan-out wires, and is configured to conduction and disconnection of the connected fan-out wire. The shielding circuit adjoining the display zone is configured to protect the liquid crystal display panel from static. An input terminal of the fuse is connected to a detection signal source. An output terminal of the fuse is connected to the fan-out wire correspondingly. An output terminal of the fan-out wire is connected to the multiplex line. The multiplex line is connected to an input terminal of the data line. The data line is connected to a thin-film transistor (TFT) in the shielding circuit and then each of the pixels in the display zone. The plurality of fuses are configured to detect a circuit in the display zone.

According to an embodiment of the present disclosure, the detection signal source comprises a detection signal line. The fuse and the detection signal line are connected in parallel.

According to an embodiment of the present disclosure, the fuse is arranged in a driver chip bonding zone of the non-display zone.

According to an embodiment of the present disclosure, a driver chip is bonded to the driver chip bonding zone after the detection of the panel is completed. A pin of the driver chip is connected to the fan-out wire correspondingly.

According to still another aspect of the present disclosure, a liquid crystal display panel having a display zone and a non-display zone surrounding the display zone is provided. A driver unit is arranged in the non-display zone. The driver unit includes a plurality of fan-out wires, a plurality of multiplex lines, a shielding circuit, and a plurality of detection lines. Each of the plurality of multiplex lines is connected to some of the plurality of fan-out wires, and is configured to conduction and disconnection of the connected fan-out wire. The shielding circuit adjoining the display zone is configured to protect the liquid crystal display panel from static. An input terminal of the detection line is connected to a detection signal source. An output terminal of the detection line is connected to the fan-out wire correspondingly. A PN junction diode is connected to the detection line. The plurality of detection lines are configured to detect a circuit in the display zone.

According to an embodiment of the present disclosure, the detection signal source comprises a detection signal line. The fuse and the detection signal line are connected in parallel.

According to an embodiment of the present disclosure, the plurality of detection lines are arranged in a driver chip bonding zone of the non-display zone.

According to an embodiment of the present disclosure, a driver chip is bonded to the driver chip bonding zone after the detection of the panel is completed; a pin of the driver chip is connected to the fan-out wire correspondingly.

According to yet another aspect of the present disclosure, a liquid crystal display including a liquid crystal display panel as provided above is also proposed.

The benefits of the present disclosure are as follows. Compared with the liquid crystal display panel of the related art, the liquid crystal display panel proposed by the present disclosure includes a plurality of detection lines substituted for the liquid crystal display panel of the related art. The plurality of detection lines are conducted forward and terminated backward. The panel is detected with the plurality of detection lines with a simple structure which is replaced with a panel detection circuit to solve the problem occurring in the related art. In the related art, the panel detection circuit occupies a larger part of the bezel, which is the cause of realization of a liquid crystal display panel with a narrow bezel.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of a common LCD of the related art.

FIG. 2 illustrates a circuit diagram of a detection circuit used in a conventional liquid crystal display panel.

FIG. 3 illustrates a schematic diagram showing an edge of a liquid crystal display panel according to a first embodiment of the present disclosure.

FIG. 4 illustrates a schematic diagram showing an edge of a liquid crystal display panel according to a second embodiment of the present disclosure.

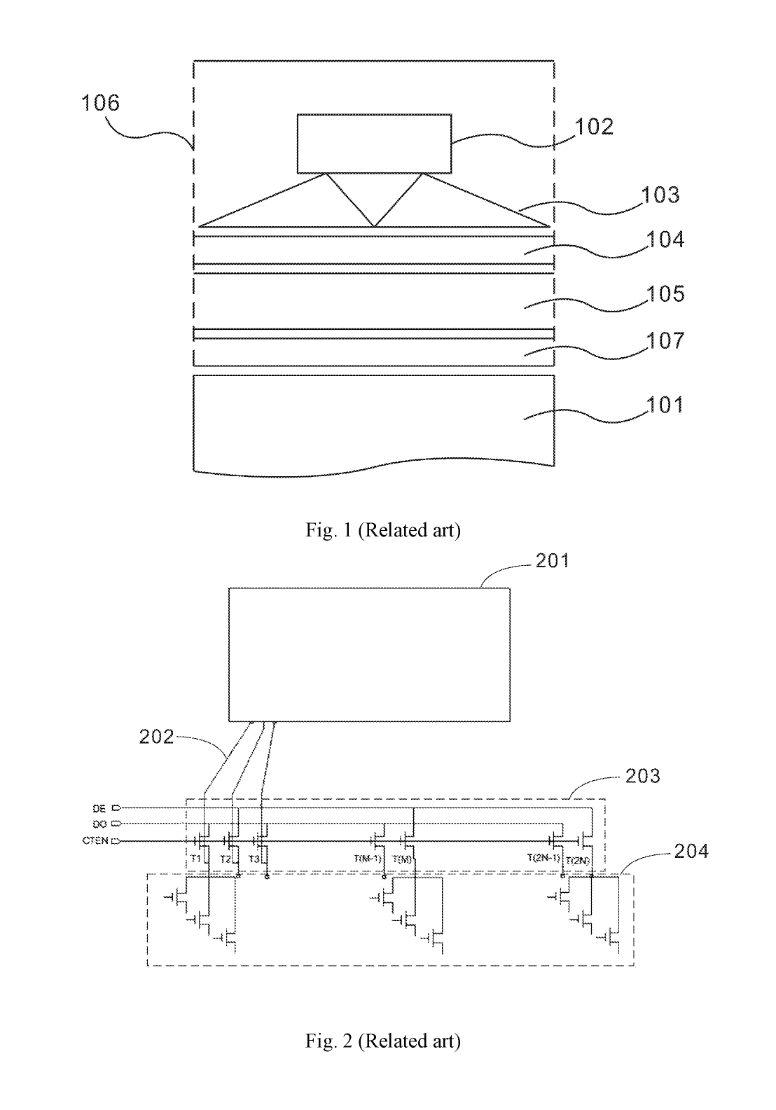

### DETAILED DESCRIPTION OF THE EMBODIMENTS

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

With respect to a liquid crystal display panel of the related art, a panel detection circuit occupies a larger part of the bezel so it is extremely hard to produce a liquid crystal display panel with a narrow bezel. The present disclosure can deal with the problem properly.

A liquid crystal display panel proposed by the present disclosure is defined by a display zone and a non-display zone. The non-display zone surrounds the display zone. A driver unit is arranged in the non-display zone. The non-display zone of the liquid crystal display panel is the zone outside the display zone. The driver unit is located on a lower bezel of the liquid crystal display panel.

The driver unit includes a plurality of fan-out wires. A detection signal is input to each pixel through one of the plurality of fan-out wires and a data line to charge and detect the pixel.

A driver signal is input to an input terminal of the fan-out wire. An output terminal of the fan-out wire extends to the display zone and is connected to a data line coupled to each pixel. The plurality of fan-out wires are configured to drive transmittance of voltage. Each of the plurality of multiplex lines is connected to some of the plurality of fan-out wires, and is configured to conduction and disconnection of the fan-out wire. A shielding circuit adjoins the display zone, and is configured to protect the liquid crystal display panel from static. An input terminal of a detection line is connected to a detection signal source. An output terminal of the detection line is connected to the fan-out wire correspondingly. The plurality of detection lines are configured to detect a circuit in the display zone. Detection signals for detecting whether pixels are charged are fed to pixels through the fan-out wires and data lines coupled to the fan-out wires.

Each of the plurality of fan-out wires is connected to each detection line. Each of the detection lines is connected to a detection signal line in parallel. A variety of detected square-wave signals are transmitted to each of the detection lines through the detection signal line, and each of the detected square-wave signals is input to each of the pixels through a data line connected to a corresponding fan-out wire. After the detection is completed, the driver chip is bonded into the non-display zone where the driver unit is located. An output pin of the driver chip is connected to the fan-out wire.

### Embodiment 1

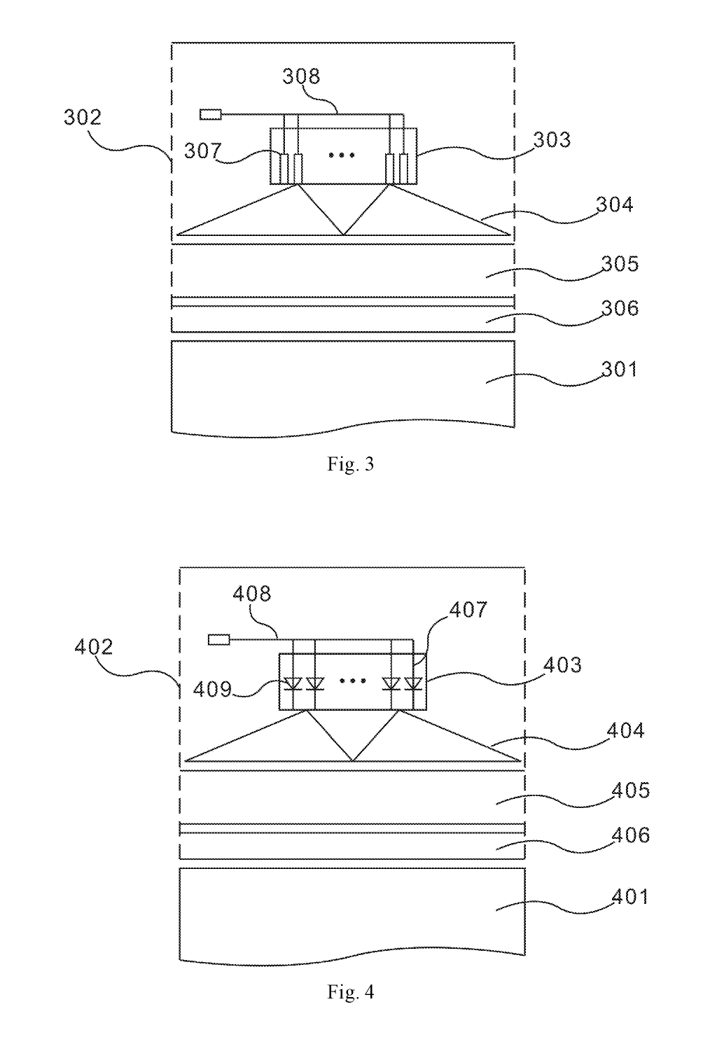

FIG. 3 illustrates a schematic diagram showing an edge of a liquid crystal display panel according to a first embodiment of the present disclosure.

The liquid crystal display panel includes a display zone 301 and a non-display zone 302. A driver unit is arranged on the non-display zone 302. The driver unit includes a detection module, a fan-out wire zone 304, a multiplex line zone 305, and a shielding circuit 306. The detection module is arranged in a driver chip bonding zone 303. The shielding circuit 306 adjoins the display zone 301. The shielding circuit 306 includes a scanning line. The scanning line is connected to a plurality of TFTs. A gate of the TFT is connected to the scanning line. A source of the TFT is connected to a data line connected to the fan-out wire zone 304. A drain of the TFT is connected to a pixel electrode. The TFT on the shielding circuit 306 is configured to protect the inside of a shielding panel against an attack of static rather than display images.

The fan-out wire zone 304 includes a plurality of fan-out wires. An input terminal of each of the plurality of fan-out wires is connected to the detection module. An output terminal of each of the plurality of fan-out wires is connected to the multiplex line. The multiplex line is connected to an input terminal of the data line. The data line is connected to the TFT in the shielding circuit 306 and then each of the pixels in the display zone 301.

The detection module includes a plurality of fuses 307. The plurality of fuses 307 correspond to the fan-out wires one on one. The plurality of fuses 307 and a detection signal line 308 are connected in parallel.

A detection signal is received by the detection signal line 308 and sent to a corresponding fan-out wire through one of the plurality of fuses 307 when the panel is detected. Further, a pixel corresponding to a data line is charged and detected. After the panel completes detection, the fuse 307 is given a threshold of electric current to fuse the fuse 307. Finally, the driver chip and a flexible printed circuit (FPC) are bonded to the non-display zone 302 in the following manufacturing process of the liquid crystal display panel to drive the liquid crystal display panel to show normal images.

### Embodiment 2

FIG. 4 illustrates a schematic diagram showing an edge of a liquid crystal display panel according to a second embodiment of the present disclosure.

The liquid crystal display panel includes a display zone 401 and a non-display zone 402. A driver unit is arranged on the non-display zone 402. The driver unit includes a detection module, a fan-out wire zone 404, a multiplex line zone 405, and a shielding circuit 406. The detection module is arranged in a driver chip bonding zone 403. The shielding circuit 406 adjoins the display zone 401. The shielding circuit 406 includes a scanning line. The scanning line is connected to a plurality of thin-film transistors (TFTs). A gate of the TFT is connected to the scanning line. A source of the TFT is connected to a data line from the fan-out wire zone 404. A drain of the TFT is connected to a pixel electrode. The pixel on the shielding circuit 406 is configured to protect the display zone 401 from static rather than display images.

The fan-out wire zone 404 includes a plurality of fan-out wires. An input terminal of each of the plurality of fan-out wires is connected to the detection module. An output terminal of each of the plurality of fan-out wires is connected to the multiplex line. The multiplex line is connected to an input terminal of the data line. The data line is connected to the TFT in the shielding circuit 406 and then each of the pixels in the display zone 401.

The detection module includes a plurality of detection lines 407. The plurality of detection lines 407 is connected to a detection signal line 408 in parallel. A PN junction diode 409 is connected to one of the plurality of detection lines 407.

A detection signal is received by the detection signal line 408 and sent to a corresponding fan-out wire through the PN junction diode 409 on the detection line 407 when the panel is detected. Further, a pixel corresponding to a data line is charged and detected. After the panel completes detection, a driver chip is bonded to the non-display zone 402 correspondingly. A pin of the driver chip is electrically connected to a connecting node of the fan-out wire for input normally displayed driver voltage to each pixel. The PN junction diode 409 is uni-directional conducted and terminated backward. It is unlikely that a normally displayed driver signal is input to the input terminal of the detection signal line 408 by moving the PN junction diode 409 backward to drive the liquid crystal display panel to show normal images.

A liquid crystal display device is proposed by the present disclosure based on the above-mentioned objective. The liquid crystal display device includes a liquid crystal display panel and a backlight module. The backlight module and the liquid crystal display panel are arranged opposite and configured to supply backlight. The liquid crystal display panel includes a display zone and a non-display zone surrounding the display zone. A driver unit is arranged in the non-display zone. The driver unit includes a plurality of fan-out wires, a plurality of multiplex lines, a shielding circuit, and a plurality of detection lines. A driver signal is input to an input terminal of the fan-out wire. An output terminal of the fan-out wire extends to the display zone and is connected to a data line connected to each pixel. The plurality of fan-out wires is configured to drive transmittance of voltage. Each of the plurality of multiplex lines is connected to some of the plurality of fan-out wires, and is configured to conduction and disconnection of the connected fan-out wire. A shielding circuit adjoining the display zone is configured to protect the liquid crystal display panel from static. An input terminal of the detection line is connected to a detection signal source. An output terminal of the detection line is connected to the fan-out wire correspondingly. The plurality of detection lines are configured to detect a circuit in the display zone.

The operating principle of the liquid crystal display device proposed by the second embodiment accords with the operating principle of the liquid crystal display device proposed by the first embodiment. In other words, the liquid crystal display device of the second embodiment can be well realized based on the operating principle introduced by the first embodiment. The specifications will not describe the liquid crystal display device of the second embodiment in detail.

Compared with the liquid crystal display panel of the related art, the liquid crystal display panel proposed by the present disclosure includes a plurality of detection lines substituted for the liquid crystal display panel of the related art. The plurality of detection lines are conducted forward and terminated backward. The panel is detected with the plurality of detection lines with a simple structure which is replaced with a panel detection circuit to solve the problem occurring in the related art. In the related art, the panel detection circuit occupies a larger part of the bezel, which is the cause of realization of a liquid crystal display panel with a narrow bezel.

While the present invention has been described in connection with what is considered the most practical and preferred embodiments, it is understood that this invention is not limited to the disclosed embodiments but is intended to cover various arrangements made without departing from the scope of the broadest interpretation of the appended claims.

What is claimed is:

1. A liquid crystal display panel, having a display zone and a non-display zone surrounding the display zone, a driver unit being arranged in the non-display zone;
the driver unit comprising:
a plurality of fan-out wires, a driver signal being input to an input terminal of the fan-out wire; an output terminal of the fan-out wire extending into the display zone and being connected to a data line connected to each pixel; the plurality of fan-out wires being configured to drive transmittance of voltage;
a plurality of multiplex lines, each of the plurality of multiplex lines being connected to some of the plurality of fan-out wires, and being configured to conduction and disconnection of the connected fan-out wire;
a shielding circuit, adjoining the display zone, and being configured to protect the liquid crystal display panel from static; and
a plurality of fuses, an input terminal of the fuse being connected to a detection signal source; an output terminal of the fuse being connected to the fan-out wire correspondingly; an output terminal of the fan-out wire being connected to the multiplex line; the multiplex line being connected to an input terminal of the data line; the data line being connected to a thin-film transistor (TFT) in the shielding circuit and then each of the pixels in the display zone; the plurality of fuses being configured to detect a circuit in the display zone.

2. The liquid crystal display panel of claim 1, wherein the detection signal source comprises a detection signal line; the fuse and the detection signal line are connected in parallel.

3. The liquid crystal display panel of claim 1, wherein the fuse is arranged in a driver chip bonding zone of the non-display zone.

4. The liquid crystal display panel of claim 3, wherein a driver chip is bonded to the driver chip bonding zone after the detection of the panel is completed; a pin of the driver chip is connected to the fan-out wire correspondingly.

5. A liquid crystal display panel, having a display zone and a non-display zone surrounding the display zone, a driver unit being arranged in the non-display zone;
the driver unit comprising:
a plurality of fan-out wires, a driver signal being input to an input terminal of the fan-out wire; an output terminal of the fan-out wire extending into the display zone and being connected to a data line connected to each pixel; the plurality of fan-out wires being configured to drive transmittance of voltage;
a plurality of multiplex lines, each of the plurality of multiplex lines being connected to some of the plurality of fan-out wires, and being configured to conduction and disconnection of the connected fan-out wire;
a shielding circuit, adjoining the display zone, and being configured to protect the liquid crystal display panel from static; and
a plurality of fuses, an input terminal of the fuse being connected to a detection signal source, an output terminal of the fuse being connected to the fan-out wire correspondingly, the plurality of fuses being configured to detect a circuit in the display zone.

6. The liquid crystal display panel of claim 5, wherein the detection signal source comprises a detection signal line; the fuse and the detection signal line are connected in parallel.

7. The liquid crystal display panel of claim 5, wherein the fuse is arranged in a driver chip bonding zone of the non-display zone.

8. The liquid crystal display panel of claim 7, wherein a driver chip is bonded to the driver chip bonding zone after the detection of the panel is completed; a pin of the driver chip is connected to the fan-out wire correspondingly.

9. A liquid crystal display panel, having a display zone and a non-display zone surrounding the display zone, a driver unit being arranged in the non-display zone;
the driver unit comprising:
a plurality of fan-out wires, a driver signal being input to an input terminal of the fan-out wire; an output terminal of the fan-out wire extending into the display zone and being connected to a data line connected to each pixel; the plurality of fan-out wires being configured to drive transmittance of voltage;
a plurality of multiplex lines, each of the plurality of multiplex lines being connected to some of the plurality of fan-out wires, and being configured to conduction and disconnection of the connected fan-out wire;
a shielding circuit, adjoining the display zone, and being configured to protect the liquid crystal display panel from static; and
a plurality of detection lines, an input terminal of the detection line being connected to a detection signal source; an output terminal of the detection line being connected to the fan-out wire correspondingly; a PN junction diode being connected to the detection line; the plurality of detection lines being configured to detect a circuit in the display zone.

10. The liquid crystal display panel of claim 9, wherein the detection signal source comprises a detection signal line; the fuse and the detection signal line are connected in parallel.

11. The liquid crystal display panel of claim 9, wherein the plurality of detection lines are arranged in a driver chip bonding zone of the non-display zone.

12. The liquid crystal display panel of claim 11, wherein a driver chip is bonded to the driver chip bonding zone after the detection of the panel is completed; a pin of the driver chip is connected to the fan-out wire correspondingly.
